(19) United States
(12) Patent Application Publication
(10) Pub. No.: US 2012/0098416 A1
(43) Pub. Date: Apr. 26, 2012

(54) APPARATUS FOR FORMING THIN LAYER, METHOD OF MANUFACTURING ORGANIC LIGHT-EMITTING DISPLAY APPARATUS USING THE SAME AND ORGANIC LIGHT-EMITTING DISPLAY APPARATUS MANUFACTURED USING THE METHOD

(76) Inventors: Sung-Hwan Cho, Yongin-city (KR); Hyea-Weon Shin, Yongin-city (KR)

(21) Appl. No.: 13/277,118

(22) Filed: Oct. 19, 2011

(30) Foreign Application Priority Data
Oct. 26, 2010 (KR) 10-2010-0104738

(51) Int. Cl. H05B 33/14; B05D 1/04; B05B 5/035

(52) U.S. Cl. 313/504; 118/621; 427/470

(57) ABSTRACT

An apparatus for forming a thin layer on a large substrate, a method of manufacturing an organic light-emitting display apparatus by using the apparatus, and an organic light-emitting display apparatus manufactured using the method.

### CROSS-REFERENCE TO RELATED PATENT APPLICATION

This application claims priority to and the benefit of Korean Patent Application No. 10-2010-0104738, filed on Oct. 26, 2010, in the Korean Intellectual Property Office, the entire content of which is incorporated herein by reference.

### BACKGROUND

1. Field

One or more aspects of the present invention relate to an apparatus for forming a thin layer, a method of manufacturing an organic light-emitting display apparatus by using the apparatus, and an organic light-emitting display apparatus manufactured using the method, and more particularly, to an apparatus for forming a thin layer that may be simply applied to produce large substrates on a mass scale, a method of manufacturing an organic light-emitting display apparatus by using the apparatus, and an organic light-emitting display apparatus manufactured using the method.

2. Description of the Related Art

Organic light-emitting display apparatuses have larger viewing angles, better contrast characteristics, and faster response speeds than other display devices, and thus have drawn attention as a next-generation display device.

In general, organic light-emitting display apparatuses have a stacked structure including an anode, a cathode, and an emission layer interposed between the anode and the cathode, and the organic light-emitting display apparatuses display images in color when holes and electrons (injected respectively from the anode and the cathode) are recombined in the emission layer to thus emit light. However, it is difficult to achieve high light-emission efficiency with such a structure, and thus intermediate layers, including an electron injection layer, an electron transport layer, a hole transport layer, a hole injection layer, etc., are optionally additionally interposed between the emission layer and each of the electrodes.

In other words, an organic light-emitting display apparatus includes intermediate layers, including an emission layer disposed between an anode and a cathode that are arranged to face (arranged opposite to) each other. The anode, the cathode, and the intermediate layers may be formed using various suitable methods, one of which is a deposition method. When an organic light-emitting display apparatus is manufactured using the deposition method, a fine metal mask (FMM) having the same pattern as a thin film to be formed is disposed to closely contact a substrate, and a thin film material is deposited over the FMM in order to form the thin film having the desired pattern.

When the intermediate layers, including the emission layer, are formed using the deposition method, the FMM for forming an organic thin film pattern on a large substrate, such as a mother glass having a fifth generation (5G) size (1100×1300 mm) or more, cannot be substantially manufactured, material efficiency is very low, and/or vacuum equipment needs to be provided on a mass scale thus increasing investment costs. As such, alternatives, for manufacturing a large-size organic light-emitting display apparatus, are needed.

### SUMMARY

Aspects of embodiments of the present invention are directed toward an apparatus for forming a thin layer that may be simply applied to produce large substrates on a mass scale and improve a manufacturing yield, a method of manufacturing an organic light-emitting display apparatus by using the apparatus, and an organic light-emitting display apparatus manufactured using the method.

According to an embodiment of the present invention, there is provided an apparatus for forming a thin layer on a substrate, the apparatus including a plurality of nozzle assemblies, wherein each of the plurality of nozzle assemblies includes: a container portion accommodating a thin layer-forming material; a nozzle unit which is disposed at one side of the container portion and in which a plurality of nozzles are disposed in a first direction; barrier ribs disposed between the nozzles; and a power supply unit applying voltage to the container portion. The apparatus is separated from the substrate by a set or predetermined distance, wherein either the apparatus or the substrate is moved relative to the other one, and wherein the apparatus forms the thin layer on the substrate when the thin layer-forming material is discharged from the nozzle unit due to an electric potential difference between the container portion and the substrate.

The nozzle assemblies may include a first nozzle assembly, a second nozzle assembly, and a third nozzle assembly; and a first container portion of the first nozzle assembly may accommodate a common layer material, a second container portion of the second nozzle assembly may accommodate an emission layer (EML) material, and a third container portion of the third nozzle assembly may accommodate a metal layer material; and the common layer material may be discharged from a first nozzle unit disposed in the first container portion, the EML material may be discharged from a second nozzle unit disposed in the second container portion, and the metal layer material may be discharged from a third nozzle unit disposed in the third container portion.

The common layer material may include a hole injection layer (HIL) material, a hole transport layer (HTL) material, and an electron transport layer (ETL) material; and the first container portion of the first nozzle assembly may include at least one first common layer container accommodating the HIL material, at least one second common layer container accommodating the HTL material, and at least one third common layer container accommodating the ETL material, so that the HIL material, the HTL material, and the ETL material are not mixed with one another.

A first power supply unit connected to the first container portion may include: a first power supply connected to the first container portion and applying voltage to the at least one first common layer container; a second power supply connected to the second container portion and applying voltage to the at least one second common layer container; and a third power supply connected to the third container portion and applying voltage to the at least one third common layer container.

When the HIL material is sprayed, voltage may be applied to the at least one first common layer container, and when the HTL material is sprayed, voltage may be applied to the at least one second common layer container, and when the ETL material is sprayed, voltage may be applied to the at least one third common layer container.

A diameter of each of a plurality of nozzles of the first nozzle unit may be from about 500 μm to about 3 mm.

The common layer material may be sprayed in a form of a spray from the first nozzle unit.

The EML material may include a red EML material, a green EML material, and a blue EML material; and the second container portion of the second nozzle assembly may include at least one first EML container accommodating the red EML material, at least one second EML container accommodating the green EML material, and at least one third EML container accommodating the blue EML material, so that the red EML material, the green EML material, and the blue EML material are not mixed with one another.

A second power supply unit connected to the second container portion may apply voltages to the first EML container, the second EML container, and the third EML container.

The second power supply unit may simultaneously or concurrently apply the same voltage to the first EML container, the second EML container, and the third EML container, and the red EML material, the green EML material, and the blue EML material may be simultaneously or concurrently discharged from the second nozzle unit.

The EML material may be discharged in a form of liquid droplets from the second nozzle unit.

A plurality of nozzles of the second nozzle unit may correspond to sub-pixels formed on the substrate in a one-to-one correspondence.

The third container portion may include only a single container accommodating the metal layer material.

A third power supply unit connected to the third container portion may apply the same voltage to the third container portion.

The metal layer material may be a silver paste.

The metal layer material may be sprayed in a form of a spray from the third nozzle unit.

A diameter of each of a plurality of nozzles of the third nozzle unit may be from about 500 μm to about 3 mm.

The barrier ribs may prevent or protect from electric field interference that occurs between the nozzles.

The barrier ribs may include plastic or rubber.

The barrier ribs may have a thickness of about 1 mm to about 3 mm.

The apparatus may further include a stage on which the substrate is disposed and which is moved between the nozzle assemblies.

The stage may include a heater heating the substrate, and the heater may thermally cure the thin layer-forming material deposited on the substrate.

According to another embodiment of the present invention, there is provided a method of manufacturing an organic light-emitting display apparatus by using an apparatus for forming a thin layer on a substrate, the method including: disposing the substrate to be separated from the apparatus by a set or predetermined distance; forming the thin layer on the substrate by moving either the apparatus or the substrate relative to the other one and spraying a thin layer-forming material onto the substrate. The apparatus for forming the thin layer on the substrate includes a plurality of nozzle assemblies, each of the plurality of nozzle assemblies including: a container portion accommodating a thin layer-forming material; a nozzle unit which is disposed at one side of the container portion and in which a plurality of nozzles are disposed in a first direction; barrier ribs disposed between the nozzles; and a power supply unit applying voltage to the container portion. The thin layer is formed on the substrate when the thin layer-forming material is sprayed onto the substrate from the nozzle unit due to an electric potential difference between the container portion and the substrate.

The nozzle assemblies may include a first nozzle assembly, a second nozzle assembly, and a third nozzle assembly; and a first container portion of the first nozzle assembly may accommodate a common layer material, a second container portion of the second nozzle assembly may accommodate an emission layer (EML) material, and a third container portion of the third nozzle assembly may accommodate a metal layer material.

The common layer material may include a hole injection layer (HIL) material, a hole transport layer (HTL) material, and an electron transport layer (ETL) material; the EML material may include a red EML material, a green EML material, and a blue EML material; the first container portion may accommodate the HIL material, the HTL material, and the ETL material so that the HIL material, the HTL material, and the ETL material are not mixed with one another; and the second container portion may accommodate the red EML material, the green EML material, and the blue EML material so that the red EML material, the green EML material, and the blue EML material are not mixed with one another.

The forming of the thin layer on the substrate may include: forming an HIL by spraying the HIL material onto the substrate by using the first nozzle assembly; curing the HIL; forming an HTL by spraying the HTL material onto the substrate by using the first nozzle assembly; curing the HTL; forming an EML by spraying the EML material onto the substrate by using the second nozzle assembly; curing the EML; forming an ETL by spraying the ETL material onto the substrate by using the first nozzle assembly; curing the ETL; forming a metal layer by spraying the metal layer material onto the substrate by using the third nozzle assembly; and curing the metal layer.

The forming of the EML may include simultaneously or concurrently spraying the red EML material, the green EML material, and the blue EML material onto the substrate from the second nozzle assembly.

The common layer material may be sprayed in a form of a spray from the first nozzle assembly.

The EML material may be sprayed in a form of liquid droplets from the second nozzle assembly.

The metal layer material may be sprayed in a form of a spray from the third nozzle assembly.

According to another aspect of the present invention, there is provided an organic light-emitting display apparatus manufactured according to one of the methods.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a schematic view of a structure of an apparatus for forming a thin layer, according to an embodiment of the present invention;

FIG. 2 is a schematic cross-sectional view of a substrate of the apparatus for forming a thin layer illustrated in FIG. 1;

FIG. 3 is a schematic cross-sectional view of an organic light-emitting display apparatus in which thin layers are formed using the apparatus for forming a thin layer illustrated in FIG. 1;

FIG. 4 is a diagram illustrating a first nozzle assembly of the apparatus for forming a thin layer illustrated in FIG. 1;

FIG. 5 is an enlarged view of region A illustrated in FIG. 4;

FIG. 6 illustrates a second nozzle assembly of the apparatus for forming a thin layer illustrated in FIG. 1;

FIG. 7 is an enlarged view of region B illustrated in FIG. 6;

FIG. 8 illustrates a third nozzle assembly of the apparatus for forming a thin layer illustrated in FIG. 1; and

FIG. 9 is an enlarged view of region C illustrated in FIG. 8.

### DETAILED DESCRIPTION

The present invention will now be described more fully with reference to the accompanying drawings in which exemplary embodiments of the invention are shown.

When the intermediate layers, including the emission layer, are formed using the deposition method, the FMM for forming an organic thin film pattern on a large substrate, such as a mother glass having a 5G size (1100×1300 mm) or more, cannot be substantially manufactured, material efficiency is very low, and vacuum equipment needs to be provided on a mass scale, thus increasing investment costs. As such, alternatives, for manufacturing a large-size organic light-emitting display apparatus, are needed.

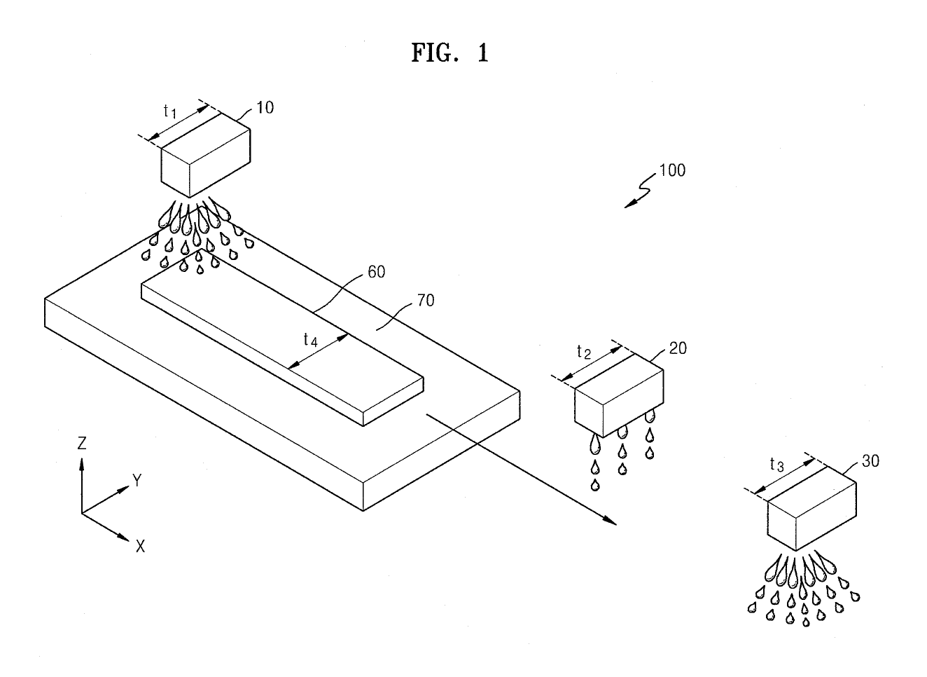

FIG. 1 is a schematic view of a structure of an apparatus 100 for forming a thin layer, according to an embodiment of the present invention.

Referring to FIG. 1, the apparatus 100 for forming a thin layer, according to the current embodiment, includes a first nozzle assembly 10, a second nozzle assembly 20, a third nozzle assembly 30, and a stage 70.

A substrate 60 is disposed on the stage 70 and is moved between the first nozzle assembly 10, the second nozzle assembly 20, and the third nozzle assembly 30 according to the movement of the stage 70. The stage 70 may include a heater installed therein. The heater heats the substrate 60 disposed on the stage 70. In more detail, after a thin layer-forming material is sprayed onto the substrate 60, the heater heats the substrate 60 and thermally cures the thin layer-forming material deposited on the substrate 60. Thus, according to an aspect of the present invention, an additional furnace or hot plate does not need to be disposed to thermally cure the thin layer-forming material deposited on the substrate 60. Also, because a thermal curing process is performed after a thin layer-forming process is performed, a manufacturing process is simplified. The heater of the stage 70 may heat the substrate 60 up to 250° C.

The substrate 60 is moved to a lower portion of the first nozzle assembly 10, and a hole injection layer (HIL), a hole transport layer (HTL), an electron transport layer (ETL), and the like may be formed on the substrate 60 by using the first nozzle assembly 10.

Also, the substrate 60 is moved to a lower portion of the second nozzle assembly 20, and an emission layer (EML) may be formed on the substrate 60 by using the second nozzle assembly 20.

Also, the substrate 60 is moved to a lower portion of the third nozzle assembly 30, and an electrode layer may be formed on the substrate 60 by using the third nozzle assembly 30.

The HIL, the HTL, the ETL, the EML, and the electrode layer may be formed on the substrate 60 by using, not a deposition method, but an electrostatic spray deposition method, as described in more detail as follows.

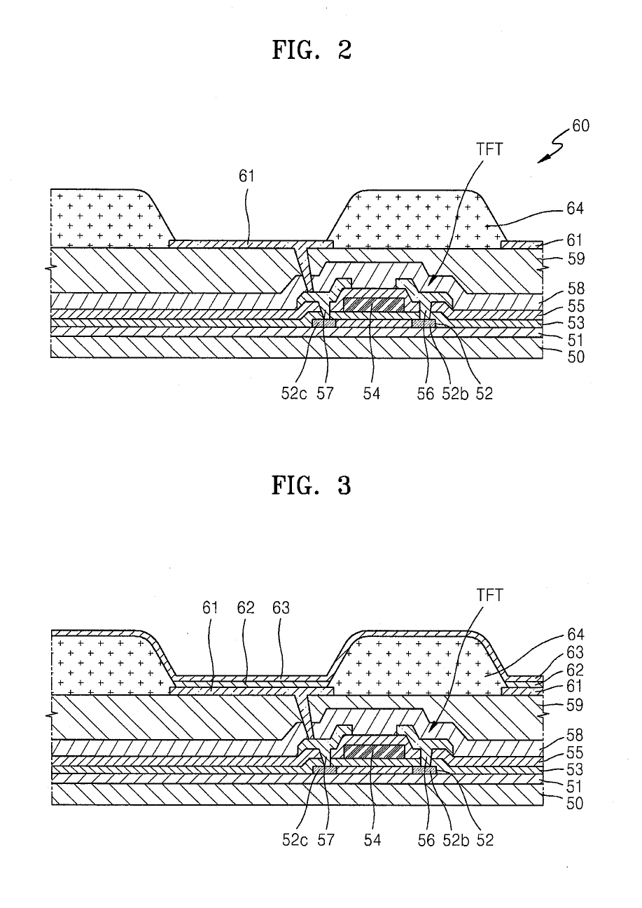

FIG. 2 is a schematic cross-sectional view of the substrate 60 of the apparatus 100 for forming a thin layer illustrated in FIG. 1.

The substrate 60 may include a thin-film transistor (TFT) formed over a base substrate 50, a pixel-defining layer 64, and the like. An HIL, an HTL, an ETL, an EML, an electrode layer, and the like may be formed on the substrate 60.

Referring to FIG. 2, a buffer layer 51 is formed on the base substrate 50 formed of glass or plastic, and the TFT and an organic light-emitting diode (OLED) may be formed over the buffer layer 51.

An active layer 52 having a set or predetermined pattern is formed on the buffer layer 51 of the base substrate 50. A gate insulating layer 53 is formed on the buffer layer 51 to cover the active layer 52, and a gate electrode 54 is formed in a set or predetermined region of an upper portion of the gate insulating layer 53. The gate electrode 54 is connected to a gate line that applies a TFT on/off signal. An interlayer insulating layer 55 is formed on the gate insulating layer 53 to cover the gate electrode 54, and source/drain electrodes 56 and 57 are formed to contact source/drain regions 52b and 52c of the active layer 52, respectively, through contact holes. A passivation layer 58 formed of SiO₂, SiNx, or the like may be formed on the interlayer insulating layer 55 to cover the source/drain electrodes 56 and 57, and a planarization layer 59 may be formed on an upper portion of the passivation layer 58 by using an organic material, such as polyimide, benzocyclobutene (BCB), or the like.

A pixel electrode 61, which functions as an anode of the OLED, is formed on an upper portion of the planarization layer 59, and the pixel defining layer 64 is formed to cover the pixel electrode 61 by using an organic material. The pixel-defining layer 64 may be formed of an organic material.

After a set or predetermined opening is formed in the pixel-defining layer 64, an intermediate layer 62 is formed between an upper portion of the pixel-defining layer 64 and an upper portion of the pixel electrode 61 exposed to the outside through an opening formed therein. In this regard, the intermediate layer 62 may include an HIL, an HTL, an EML, and an ETL.

However, the present invention is not limited to the structure described above, and an organic light-emitting display apparatus may have various suitable structure types.

FIG. 3 is a schematic cross-sectional view of an organic light-emitting display apparatus in which thin layers are formed using the apparatus 100 for forming a thin layer illustrated in FIG. 1.

Referring to FIG. 3, the intermediate layer 62 may be formed on the substrate 60 by using the apparatus 100 for forming a thin layer illustrated in FIG. 1. The intermediate layer 62 may be formed on the pixel electrode 61.

The intermediate layer 62 may be a low-molecular weight organic layer or a polymer organic layer. When the intermediate layer 62 is a low-molecular weight organic layer, the intermediate layer 62 may have a single or multi-layer structure including at least one selected from the group consisting of an HIL, an HTL, an EML, an ETL, an electron injection layer (EIL), etc. Examples of available organic materials may include copper phthalocyanine (CuPc), N,N′-di(naphthalene-1-yl)-N,N′-diphenyl-benzidine (NPB), tris-8-hydroxyquinoline aluminum (Alq3), etc.

Alternatively, when the intermediate layer 62 is a polymer organic layer, the intermediate layer 162 may have a structure including an HTL and an EML. In this regard, Poly(3,4-ethylenedioxythiophene)(PEDOT) is used to form the HTL, and a poly-phenylenevinylene (PPV)-based or polyfluorene-based polymer organic material, or the like, may be used to form the EML.

The intermediate layer 62 is not limited thereto, and various suitable embodiments may be applied to form the intermediate layer 62.

An opposite electrode 63 is formed over the substrate 60 so as to completely cover the intermediate layer 62. The opposite electrode 63 may function as a common electrode. The pixel electrode 61 functions as an anode, and the opposite electrode 63 functions as a cathode. Obviously, polarities of the pixel electrode 61 and the opposite electrode 63 may be the opposite, that is, the pixel electrode 61 functions as a cathode, and the opposite electrode 63 functions as an anode.

The intermediate layer 62 and the opposite electrode 63 are formed by the apparatus 100 for forming a thin layer illustrated in FIG. 1. Hereinafter, the apparatus 100 for forming a thin layer illustrated in FIG. 1 will be described in more detail.

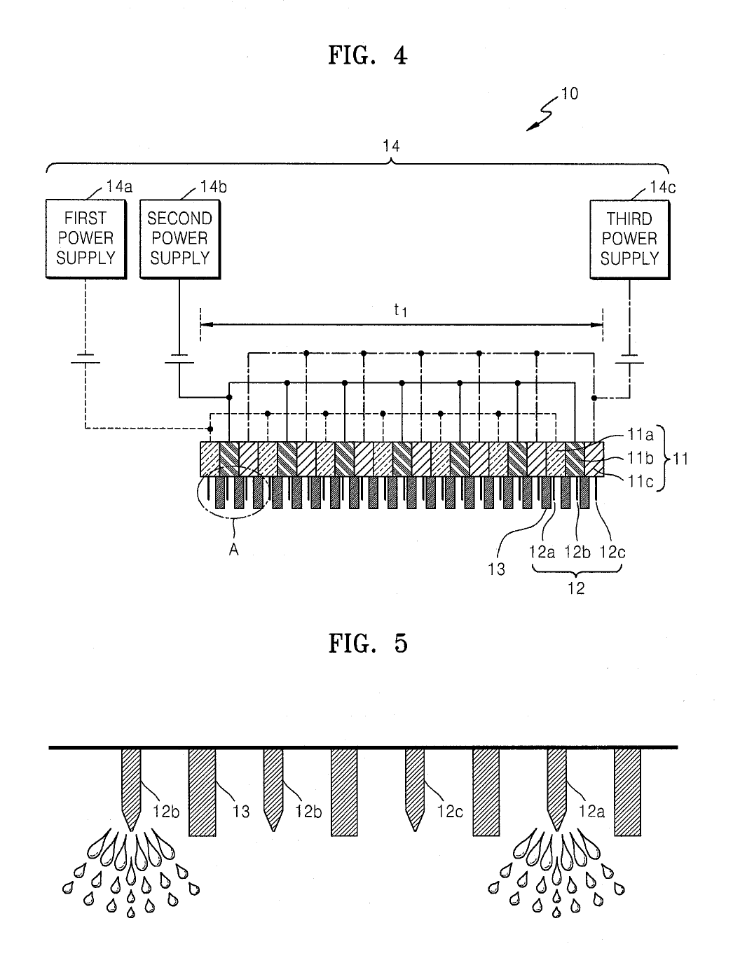

FIG. 4 is a diagram illustrating the first nozzle assembly 10 of the apparatus 100 for forming a thin layer illustrated in FIG. 1.

Referring to FIG. 4, the first nozzle assembly 10 includes a first container portion 11, a first nozzle unit 12, barrier ribs 13, and a first power supply unit including first, second, and third power supply units 14a, 14b, and 14c.

Container portions may accommodate a thin layer-forming material, and in particularly, the first container portion 11 may accommodate a common layer material. The first container portion 11 may include a plurality of first common layer containers 11a, a plurality of second common layer containers 11b, and a plurality of third common layer containers 11c. The common layer material may be an HIL material, an HTL material, and an ETL material. Each of the first common layer containers 11a may accommodate the HIL material, each of the second common layer containers 11b may accommodate the HTL material, and each of the third common layer containers 11c may accommodate the ETL material. The common layer materials are not mixed with one another due to the first common layer container 11a, the second common layer container 11b, and the third common layer container 11c. Containers of the same type may be sequentially disposed not to be adjacent to each other.

A length t₁ of the first container portion 11 may be equal to or greater than a length t₄ of one side of the substrate 60 (see also FIG. 1). Since the first container portion 11 (having the length t₁ that is equal to or is greater than the length t₄ of one side of the substrate 60) is moved relative to the substrate 60, or the substrate 60 is moved relative to the first container portion 11, the apparatus 100 for forming a thin layer may easily form a thin layer on a large-size substrate.

The first nozzle unit 12 may be disposed at one side of the first container portion 11. The common layer material accommodated in the first container portion 11 is discharged from the first nozzle unit 12. The first nozzle unit 12 may include a plurality of nozzles 12a, 12b, and 12c. A nozzle is disposed in a common layer container. In more detail, the nozzles 12a are connected to the first common layer containers 11a, the nozzles 12b are connected to the second common layer containers 11b, and the nozzles 12c are connected to the third common layer containers 11c. Thus, the HIL material accommodated in the first common layer container 11a is discharged from the nozzle 12a, the HTL material accommodated in the second common layer container 11b is discharged from the nozzle 12b, and the ETL material accommodated in the third common layer container 11c is discharged from the nozzle 12c.

A diameter of each of the nozzles 12a, 12b, and 12c of the first nozzle unit 12 may be from 500 μm to 3 mm (or from about 500 μm to about 3 mm).

The barrier ribs 13 may be disposed between the nozzles 12a, 12b, and 12c of the first nozzle unit 12. The barrier ribs 13 may prevent electric field interference that occurs between the nozzles 12a, 12b, and 12c.

The first container portion 11 may be connected to the first power supply unit 14. The first power supply unit 14 applies voltage to the first container portion 11 so as to form an electric potential difference between the first container portion 11 and the substrate 60. The first power supply unit 14 may be a direct current (DC) or alternating current (AC) power supply unit. The first power supply unit 14 applies voltage to the first container portion 11 so that the electric potential difference formed between the first container portion 11 and the substrate 60 may be from 2 kV to 15 kV (or from about 2 kV to about 15 kV). When the first power supply unit 14 forms the electric potential difference between the first container portion 11 and the substrate 60, the common layer material accommodated in the first container portion 11 is discharged from the nozzles 12a, 12b, and 12c of the first nozzle unit 12. In this regard, the common layer material may be discharged from the first nozzle unit 12 as a spray. As the electric potential difference between the first container portion 11 and the substrate 60 increases, the spray range of the common layer material is increased.

The first power supply unit 14 may include the first power supply 14a, the second power supply 14b, and the third power supply 14c. The first power supply 14a may be connected to each of the first common layer containers 11a and may apply voltage to each of the first common layer containers 11a. The second power supply 14b may be connected to each of the second common layer containers 11b and may apply voltage to each of the second container common layer containers 11b. The third power supply 14c may be connected to each of the third common layer containers 11c and may apply voltage to each of the third common layer containers 11c.

Each of the first power supply 14a, the second power supply 14b, and the third power supply 14c may apply a voltage to each of the first common layer containers 11a, the second common layer containers 11b, and the third common layer containers 11c, respectively, thereby spraying the common layer material.

In more detail, when the HIL is formed, the first power supply 14a may apply voltage to each of the first common layer containers 11a, thereby spraying the HIL material (accommodated in the first common layer containers 11a) onto the substrate 60. In this regard, the second power supply 14b and the third power supply 14c do not apply voltages to each of the second common layer containers 11b and the third common layer containers 11c, respectively.

When the HTL is formed, the second power supply 14b may apply voltage to each of the second common layer containers 11b, thereby spraying the HTL material (accommodated in the second common layer containers 11b) onto the substrate 60. In this regard, the first power supply 14a and the third power supply 14c do not apply voltages to each of the first common layer containers 11a and the third common layer containers 11c, respectively.

When the ETL is formed, the third power supply 14c may apply voltage to the each of third common layer containers 11c, thereby spraying the ETL material (accommodated in the third common layer containers 11c) onto the substrate 60. In this regard, the first power supply 14a and the second power supply 14b do not apply voltages to each of the first common layer containers 11a and the second common layer containers 11b, respectively.

FIG. 5 is an enlarged view of region A illustrated in FIG. 4.

Referring to FIG. 5, the barrier ribs 13 are disposed between the nozzles 12a, 12b, and 12c of the first nozzle unit 12. Here, in one embodiment, the HIL material is sprayed only from the nozzles 12a, and the HTL material and the ETL material are not sprayed from the nozzles 12b and 12c because voltage is only applied by the first power supply 14a to the first common layer containers 11a.

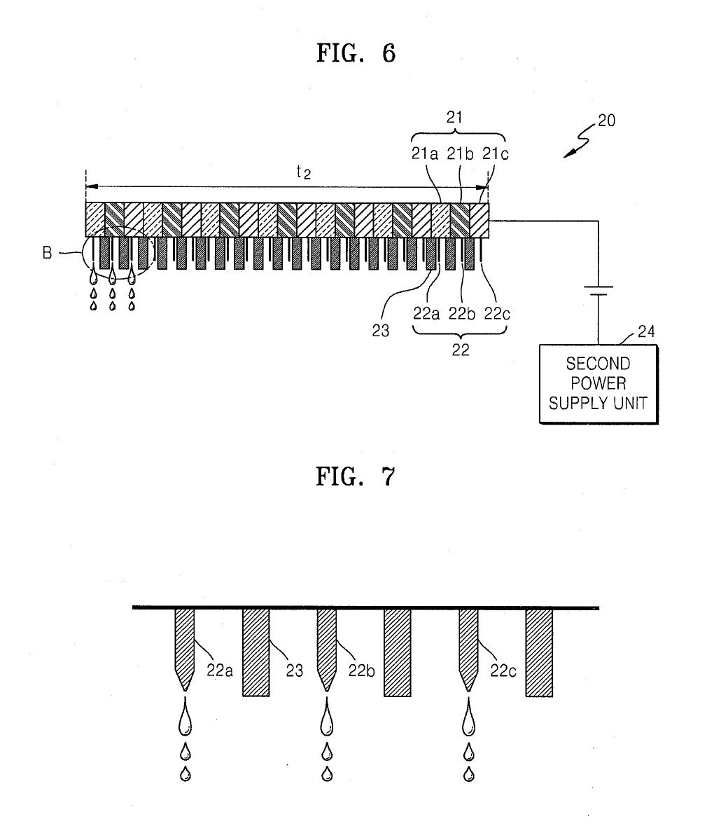

FIG. 6 illustrates the second nozzle assembly 20 of the apparatus 100 for forming a thin layer illustrated in FIG. 1.

Referring to FIG. 6, the second nozzle assembly 20 may include a second container portion 21, a second nozzle unit 22, barrier ribs 23, and a second power supply unit 24.

The second container portion 21 may accommodate an EML material. The second container portion 21 may include a plurality of first EML containers 21a, a plurality of second EML containers 21b, and a plurality of third EML containers 21c. The EML material may be a red EML material, a green EML material, or a blue EML material. The first EML containers 21a may accommodate the red EML material, the second EML containers 21b may accommodate the green EML material, and the third EML containers 21c may accommodate the blue EML material. The EML materials are not mixed with one another due to the first EML containers 21a, the second EML containers 21b, and the third EML containers 21c.

Containers of the same type may be sequentially disposed not to be adjacent to one another.

A length t₂ of the second container portion 21 may be equal to or greater than the length t₄ of one side of the substrate 60 (see also FIG. 1). Since the second container portion 21 (having the length t₂ that is equal to or is greater than the length t4 of one side of the substrate 60) is moved relative to the substrate 60, or the substrate 60 is moved relative to the second container portion 21, the apparatus 100 for forming a thin layer may easily form a thin layer on a large-size substrate.

The second nozzle unit 22 may be disposed at one side of the second container portion 21. The EML material accommodated in the second container portion 21 is discharged from the second nozzle unit 22. The second nozzle unit 22 may include a plurality of nozzles 22a, 22b, and 22c.

A nozzle is disposed in an EML container. In more detail, the nozzle 22a is connected to the first EML container 21a, the nozzle 22b is connected to the second EML container 21b, and the nozzle 22c is connected to the third EML container 21c. Thus, the red EML material accommodated in the first EML container 21a is discharged from the nozzle 22a, the green EML material accommodated in the second EML container 21b is discharged from the nozzle 22b, and the blue EML material accommodated in the third EML container 21c is discharged from the nozzle 22c.

A diameter of each of the nozzles 22a, 22b, and 22c of the second nozzle unit 22 may be 30 μm (or about 30 μm).

The barrier ribs 23 may be disposed between the nozzles 22a, 22b, and 22c of the second nozzle unit 22. The barrier ribs 23 may prevent or protect from electric field interference that occurs between the nozzles 22a, 22b, and 22c.

The second container portion 21 may be connected to the second power supply unit 24. The second power supply unit 24 applies voltage to the second container portion 21 so as to form an electric potential difference between the second container portion 21 and the substrate 60. The second power supply unit 24 may be a DC or AC power supply unit. The second power supply unit 24 applies voltage to the second container portion 21, thereby generating an electric potential difference between the second container portion 21 and the substrate 60. When the electric field difference between the second container portion 21 and the substrate 60 is generated due to the second power supply unit 24, the EML material accommodated in the second container portion 21 is sprayed from the nozzles 22a, 22b, and 22c of the second nozzle unit 22. In this regard, the EML material may be sprayed in the form of liquid droplets from the second nozzle unit 22. Since the EML material is sprayed in the form of liquid droplets and is deposited on the substrate 60, the EML material sprayed from the second nozzle unit 22 may fall on the pixel electrode 61, thereby forming sub-pixels.

The second power supply unit 24 may apply voltage to all portions of the second container portion 21. In more detail, the second power supply unit 24 may apply the same voltage to all of the containers including the first EML container 22a, the second EML container 22b, and the third EML container 22c. When the second power supply unit 24 simultaneously or currently applies the same voltage to the first EML container 22a, the second EML container 22b, and the third EML container 22c, the red EML material, the green EML material, and the blue EML material may be simultaneously or concurrently sprayed from each of the first EML container 22a, the second EML container 22b, and the third EML container 22c. Thus, a red EML, a green EML, and a blue EML may be simultaneously or currently formed on the substrate 60.

FIG. 7 is an enlarged view of region B illustrated in FIG. 6.

Referring to FIG. 7, the barrier ribs 23 are disposed between the nozzles 22a, 22b, and 22c of the second nozzle unit 22. The EML materials are sprayed from all of the nozzles 22a, 22b, and 22c because voltages are simultaneously or concurrently applied by the second power supply unit 24 to the first EML container 22a, the second EML container 22b, and the third EML container 22c.

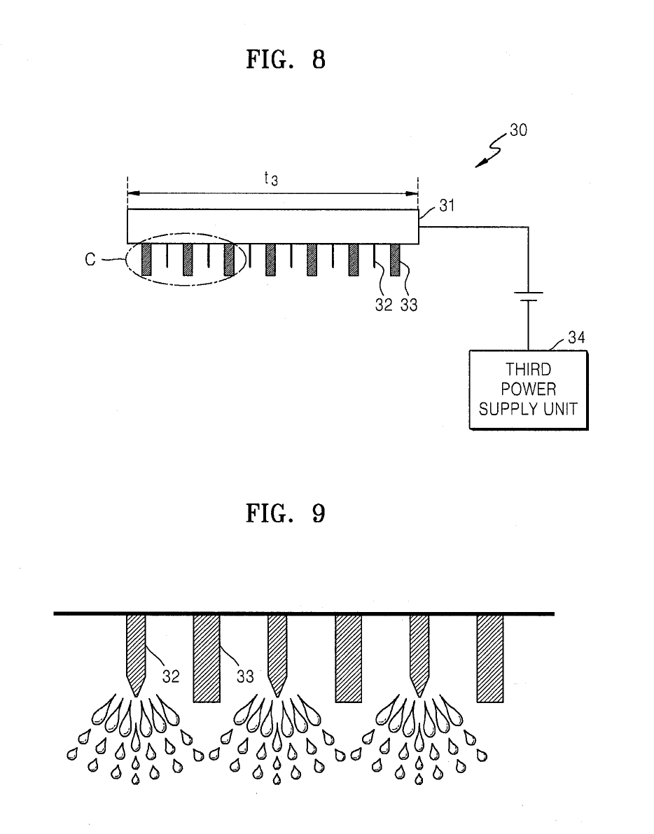

FIG. 8 illustrates the third nozzle assembly 30 of the apparatus 100 for forming a thin layer illustrated in FIG. 1.

Referring to FIG. 8, the third nozzle assembly 30 includes a third container portion 31, a third nozzle unit 32, barrier ribs 33, and a third power supply unit 34.

The third container portion 31 may accommodate a metal layer material. Since the third container portion 31 accommodates one type of metal layer material, the third container portion 31 does not include a plurality of containers, like the first and second container portions 11 and 21, and may include one internal space in which the metal layer material is to be accommodated. The metal layer material may be liquid silver (Ag) or aluminum (Al), or a silver paste.

A length t₃ of the third container portion 31 may be equal to or greater than the length t₄ of one side of the substrate 60 (see also FIG. 1). Since the third container portion 31 (having the length t₃ that is equal to or is greater than the length t4 of one side of the substrate 60) is moved relative to the substrate 60, or the substrate 60 is moved relative to the third container portion 31, the apparatus 100 for forming a thin layer may easily form a thin layer on a large-size substrate.

The third nozzle unit 32 may be disposed at one side of the third container portion 31. The metal layer material accommodated in the third container portion 31 is discharged from the third nozzle unit 32. The third nozzle unit 32 may include a plurality of nozzles.

A diameter of each of the nozzles of the third nozzle unit 32 may be from 500 μm to 3 mm (from about 500 μm to about 3 mm).

The barrier ribs 33 may be disposed between the nozzles of the third nozzle unit 32. The barrier ribs 33 may prevent or protect from electric field interference that occurs between the nozzles of the third nozzle unit 32.

The third container portion 31 may be connected to the third power supply unit 34. The third power supply unit 34 applies voltage to the third container portion 31 so as to form an electric potential difference between the third container portion 31 and the substrate 60. The third power supply unit 34 may be a DC or AC power supply unit. The third power supply unit 34 applies voltage to the third container portion 31, thereby generating the electric potential difference between the third container portion 31 and the substrate 60. When the electric potential difference between the third container portion 31 and the substrate 60 is generated by the third power supply unit 34, the metal layer material accommodated in the third container portion 31 is sprayed from the third nozzle unit 32. In this regard, the metal layer material may be sprayed in the form of a spray onto a wide portion of the substrate 60 from the third nozzle unit 32. The metal layer material sprayed from the third nozzle unit 32 may be used to form an opposite electrode (63 of FIG. 3).

The third power supply unit 34 may apply voltage to all portions of the third container portion 31. Thus, the metal layer material is sprayed from the third nozzle unit 32 disposed in the third container portion 31.

FIG. 9 is an enlarged view of region C illustrated in FIG. 8.

Referring to FIG. 9, the barrier ribs 33 are disposed between the nozzles of the third nozzle unit 32. The metal layer material is sprayed from all nozzles of the third nozzle unit 32.

In this way, according to an aspect of the present invention, the area of a nozzle assembly does not need to be the same as the area of a substrate, and when a length of one side of the nozzle assembly equals to or is greater than a length of one side of the substrate, the nozzle assembly and the substrate may be moved relative to each other, and thin layers (HTL, HIL, EML, metal layer, etc.) may be formed on the substrate so that the apparatus 100 for forming a thin layer may be simply applied to produce large substrates of a fourth generation (4G) size or more on a mass scale.

A process of forming a thin layer on the substrate 60 will now be described in more detail.

First, the substrate 60, having the base substrate 50 on which the TFT, the pixel electrode 61, the pixel-defining layer 64, and the like are formed, is disposed on the stage 70.

After that, the stage 70 is moved in an x-direction, and the first nozzle assembly 10 sprays an HIL material onto the substrate 60. Voltage is applied only to a first common layer container 11a of the first nozzle assembly 10 in which the HIL material is accommodated, so that an electric potential difference between the first common layer container 11a and the substrate 60 may be generated and the HIL material may be sprayed onto the substrate 60. The HIL material is sprayed in the form of a spray and is deposited on the substrate 60.

After the HIL material is sprayed, the HIL material deposited on the substrate 60 is cured. The heater installed in the stage 70 heats the substrate 60 to thermally cure the HIL material, thereby forming an HIL.

Subsequently, an HTL material is sprayed by the first nozzle assembly 10 onto the substrate 60. Voltage is applied only to the second common layer container 11b of the first nozzle assembly 10 in which the HTL material is accommodated, so that an electric potential difference between the second common layer container 11b and the substrate 60 may be generated and the HTL material may be sprayed onto the substrate 60. The HTL material is sprayed in the form of a spray. When the HTL material is sprayed, the stage 70 is moved in a positive (+) x-direction or a negative (−) x-direction. Thus, the HTL material is deposited on the substrate 60.

The HTL material, which is deposited on the substrate 60 after the HTL material is sprayed, is cured. The heater installed in the stage 70 heats the substrate 60 to thermally cure the HTL material, thereby forming an HTL.

Subsequently, the stage 70 is moved to be adjacent to the second nozzle assembly 20. EML materials, i.e., a red EML material, a green EML material, and a blue EML material are sprayed by the second nozzle assembly 20 onto the substrate 60. The red EML material, the green EML material, and the blue EML material are sprayed in the form of liquid droplets from the second nozzle assembly 20 and are deposited on the substrate 60 to correspond to the pixel electrode 61, thereby forming a red EML, a green EML, and a blue EML. The second power supply unit 24 may simultaneously or concurrently apply voltages to the first EML container 22a, the second EML container 22b, and the third EML container 22c so that the red EML material, the green EML material, and the blue EML material may be simultaneously or concurrently sprayed onto the substrate 60. Thus, according to an embodiment of the present invention, a red EML, a green EML, and a blue EML may be formed without using a mask. Also, the red EML, the green EML, and the blue EML may be simultaneously or concurrently formed so that a production process may be simplified and productivity may be improved. Also, unlike in a comparable deposition method, the red EML material, the green EML material, and the blue EML material are deposited only in a necessary region so that material costs may be reduced.

When the EML materials are sprayed, the stage 70 is moved in the positive (+) x-direction or the negative (−) x-direction. Thus, the EML materials are deposited on the substrate 60.

The EML materials, which are deposited on the substrate 60 after the EML materials are sprayed, are cured. The heater installed in the stage 70 heats the substrate 60 to thermally cure the EML materials, thereby forming an EML.

Subsequently, the stage 70 is moved to be adjacent to the first nozzle assembly 10. An ETL material is sprayed by the first nozzle assembly 10 onto the substrate 60. Voltage is applied only to the third common layer container 11c of the first nozzle assembly 10 in which an ETL material is accommodated. An electric potential difference between the third common layer container 11c and the substrate 60 is generated, and the ETL material is sprayed onto the substrate 60. The ETL material is sprayed in the form of a spray. When the ETL material is sprayed, the stage 70 is moved in the positive (+) x-direction or the negative (−) x-direction. Thus, the ETL material is deposited on the substrate 60 so as to cover the EML.

After the ETL material is sprayed, the ETL material deposited on the substrate 60 is cured. The heater installed in the stage 70 heats the substrate 60 to thermally cure the ETL material, thereby forming an ETL.

Subsequently, the stage 70 is moved to be adjacent to the third nozzle assembly 30. A metal layer material is sprayed by the third nozzle assembly 30 onto the substrate 60. The metal layer material is sprayed in the form of a spray from the third nozzle assembly 30. The third power supply unit 34 applies voltage to the third container portion 31 so that the metal layer material may be sprayed onto the substrate 60. The sprayed metal layer material may be deposited on the substrate 60.

The metal layer material, which is deposited on the substrate 60 after the metal layer material is sprayed, is cured. The heater installed in the stage 70 heats the substrate 60 to thermally cure the metal layer material, thereby forming the opposite electrode 63.

In this way, according to an aspect of the present invention, since an opposite electrode as well as a common layer and an EML are formed using a series of processes, a manufacturing process may be simplified, and productivity may be improved. Furthermore, a thin layer-forming process, according to an embodiment of the present invention, may be performed even at atmospheric pressure so that a high-priced vacuum chamber may not need to be provided, thereby reducing facility investment costs.

According to an aspect of the present invention, an apparatus for forming a thin layer may be simply applied to produce large substrates on a mass scale, and manufacturing yield may be improved.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. An apparatus for forming a thin layer on a substrate, the apparatus comprising:
a plurality of nozzle assemblies,
wherein each of the plurality of nozzle assemblies comprises:
a container portion for accommodating a thin layer-forming material;
a nozzle unit at one side of the container portion and in which a plurality of nozzles are disposed in a first direction;
barrier ribs between the nozzles; and
a power supply unit for applying voltage to the container portion, wherein
the apparatus is separated from the substrate by a set distance, wherein
either the apparatus or the substrate is moved relative to the other one, and wherein
the apparatus is configured to form the thin layer on the substrate when the thin layer-forming material is discharged from the nozzle unit due to an electric potential difference between the container portion and the substrate.

2. The apparatus of claim 1, wherein the nozzle assemblies comprise a first nozzle assembly, a second nozzle assembly, and a third nozzle assembly, and
a first container portion of the first nozzle assembly is configured to accommodate a common layer material, a second container portion of the second nozzle assembly is configured to accommodate an emission layer (EML) material, and a third container portion of the third nozzle assembly is configured to accommodate a metal layer material; and a first nozzle unit disposed in the first container portion is configured to discharge the common layer material, a second nozzle unit disposed in the second container portion is configured to discharge the EML material, and a third nozzle unit disposed in the third container portion is configured to discharge the metal layer material.

3. The apparatus of claim 2, wherein the common layer material comprises a hole injection layer (HIL) material, a hole transport layer (HTL) material, and an electron transport layer (ETL) material; and the first container portion of the first nozzle assembly comprises a first common layer container for accommodating the HIL material, a second common layer container for accommodating the HTL material, and a third common layer container for accommodating the ETL material, so that the HIL material, the HTL material, and the ETL material are not mixed with one another.

4. The apparatus of claim 3, wherein a first power supply unit connected to the first container portion comprises:
a first power supply connected to the first container portion and for applying voltage to the first common layer container;
a second power supply connected to the second container portion and for applying voltage to the second common layer container; and
a third power supply connected to the third container portion and for applying voltage to the third common layer container.

5. The apparatus of claim 4, wherein, when the HIL material is sprayed, voltage is applied to the first common layer container, and when the HTL material is sprayed, voltage is applied to the second common layer container, and when the ETL material is sprayed, voltage is applied to the third common layer container.

6. The apparatus of claim 3, wherein a diameter of each of a plurality of nozzles of the first nozzle unit is from about 500 μm to about 3 mm.

7. The apparatus of claim 3, wherein the common layer material is sprayed in a form of a spray from the first nozzle unit.

8. The apparatus of claim 2, wherein the EML material comprises a red EML material, a green EML material, and a blue EML material; and the second container portion of the second nozzle assembly comprises a first EML container for accommodating the red EML material, a second EML container for accommodating the green EML material, and a third EML container for accommodating the blue EML material, so that the red EML material, the green EML material, and the blue EML material are not mixed with one another.

9. The apparatus of claim 8, wherein a second power supply unit connected to the second container portion is configured to apply voltages to the first EML container, the second EML container, and the third EML container.

10. The apparatus of claim 9, wherein the second power supply unit is configured to concurrently apply the same voltage to the first EML container, the second EML container, and the third EML container to concurrently discharge the red EML material, the green EML material, and the blue EML material from the second nozzle unit.

11. The apparatus of claim 8, wherein the EML material is discharged in a form of liquid droplets from the second nozzle unit.

12. The apparatus of claim 8, wherein a plurality of nozzles of the second nozzle unit correspond to sub-pixels formed on the substrate in a one-to-one correspondence.

13. The apparatus of claim 2, wherein the third container portion comprises only a single container for accommodating the metal layer material.

14. The apparatus of claim 13, wherein a third power supply unit connected to the third container portion is configured to apply the same voltage to the third container portion.

15. The apparatus of claim 2, wherein the metal layer material is a silver paste.

16. The apparatus of claim 2, wherein the metal layer material is sprayed in a form of a spray from the third nozzle unit.

17. The apparatus of claim 2, wherein a diameter of each of a plurality of nozzles of the third nozzle unit is from about 500 μm to about 3 mm.

18. The apparatus of claim 1, wherein the barrier ribs is configured to protect from electric field interference that occurs between the nozzles.

19. The apparatus of claim 1, wherein the barrier ribs comprise plastic or rubber.

20. The apparatus of claim 1, wherein the barrier ribs have a thickness of about 1 mm to about 3 mm.

21. The apparatus of claim 1, further comprising a stage on which the substrate is disposed and which is moved between the nozzle assemblies.

22. The apparatus of claim 21, wherein the stage comprises a heater for heating the substrate, and for thermally curing the thin layer-forming material deposited on the substrate.

23. A method of manufacturing an organic light-emitting display apparatus by using an apparatus for forming a thin layer on a substrate, the method comprising:
disposing the substrate to be separated from the apparatus by a set distance;
forming the thin layer on the substrate by moving either the apparatus or the substrate is moved relative to the other one and spraying a thin layer-forming material is onto the substrate,
wherein the apparatus for forming the thin layer on the substrate comprises a plurality of nozzle assemblies, each of the plurality of nozzle assemblies comprising:
a container portion accommodating a thin layer-forming material;
a nozzle unit disposed at one side of the container portion and in which a plurality of nozzles are disposed in a first direction;
barrier ribs disposed between the nozzles; and
a power supply unit applying voltage to the container portion,
wherein the thin layer is formed on the substrate when the thin layer-forming material is sprayed onto the substrate from the nozzle unit due to an electric potential difference between the container portion and the substrate.

24. The method of claim 23, wherein the nozzle assemblies comprise a first nozzle assembly, a second nozzle assembly, and a third nozzle assembly; and a first container portion of the first nozzle assembly accommodates a common layer material, a second container portion of the second nozzle assembly accommodates an emission layer (EML) material, and a third container portion of the third nozzle assembly accommodates a metal layer material.

25. The method of claim 24, wherein the common layer material comprises a hole injection layer (HIL) material, a hole transport layer (HTL) material, and an electron transport layer (ETL) material; the EML material comprises a red EML material, a green EML material, and a blue EML material; the first container portion accommodates the HIL material, the HTL material, and the ETL material so that the HIL material, the HTL material, and the ETL material are not mixed with one another; and the second container portion accommodates the red EML material, the green EML material, and the blue EML material so that the red EML material, the green EML material, and the blue EML material are not mixed with one another.

26. The method of claim 25, wherein the forming of the thin layer on the substrate comprises:
forming an HIL by spraying the HIL material onto the substrate by using the first nozzle assembly;
curing the HIL;
forming an HTL by spraying the HTL material onto the substrate by using the first nozzle assembly;
curing the HTL;
forming an EML by spraying the EML material onto the substrate by using the second nozzle assembly;
curing the EML;
forming an ETL by spraying the ETL material onto the substrate by using the first nozzle assembly;
curing the ETL;
forming a metal layer by spraying the metal layer material onto the substrate by using the third nozzle assembly; and
curing the metal layer.

27. The method of claim 26, wherein the forming of the EML comprises concurrently spraying the red EML material, the green EML material, and the blue EML material onto the substrate from the second nozzle assembly.

28. The method of claim 24, wherein the common layer material is sprayed in a form of a spray from the first nozzle assembly.

29. The method of claim 24, wherein the EML material is sprayed in a form of liquid droplets from the second nozzle assembly.

30. The method of claim 24, wherein the metal layer material is sprayed in a form of a spray from the third nozzle assembly.

31. An organic light-emitting display apparatus manufactured according to the method of claim 23.
